(19) United States
(12) Patent Application Publication
(10) Pub. No.: US 2026/0324443 A1
(43) Pub. Date: Oct. 15, 2026

(54) POWER SEMICONDUCTOR DEVICE INCLUDING TWO DIFFERENT TYPES OF POWER TRANSISTOR DIES AND FABRICATION METHOD

(71) Applicant: Infineon Technologies AG, Neubiberg (DE)

(72) Inventors: Tomas Reiter, Ottobrunn (DE); Michael Niendorf, Verl (DE); Julius Schapdick, Dortmund (DE); Nikolaj Gorte, Altenbeken (DE); Cédric Ouvrard, München (DE)

(21) Appl. No.: 19/463,257

(22) Filed: Jan. 29, 2026

(30) Foreign Application Priority Data
Jan. 30, 2025 (DE) 102025103483.4

(51) Int. Cl. H10W 44/00; H10W 90/00; H10W 90/10

(52) U.S. Cl. CPC H10W 44/501; H10W 90/10; H10W 90/753; H10W 90/755

(57) ABSTRACT

A power semiconductor device incudes: a substrate having a patterned metallization on an electrically insulating body; a first power transistor die of a first transistor type attached to the substrate; a second power transistor die of a second transistor type different from the first transistor type attached to the substrate; and a stray inductance magnifier electrically connected to the first power transistor die and configured to increase a stray inductance of the first power transistor die with respect to a stray inductance of the second power transistor die. Load terminals of the first power transistor die and load terminals of the second power transistor die are electrically connected in parallel via the patterned metallization to form a first topological switch.

### TECHNICAL FIELD

The present disclosure relates to a power semiconductor device comprising at least a first and a second power transistor die which are of different types of power transistor dies, as well as to a method for fabricating such a power semiconductor device.

### BACKGROUND

Power semiconductor devices, for example power semiconductor modules or packages, may comprise two or more power transistor dies which are electrically connected to form one or more topological switches. Such power semiconductor devices may for example be part of a power converter or an inverter, in particular an inverter of an electric vehicle. Furthermore, in many applications such power semiconductor devices may be operated in light or medium load current conditions most of the time and in heavy load current conditions only comparatively sparsely. Therefore, the topological switches of such power semiconductor devices may comprise a first power transistor die configured to support light or medium load current operations and a second power transistor die configured to support the first power transistor die during heavy load current operations. The first power transistor die may be of a highly efficient but comparatively expensive type and the second power transistor die may be of a less efficient but cheaper type. However, since the first and second power transistor dies are of different types, correctly driving both power transistor dies with respect to each other may be particularly important but also comparatively complex, increasing costs of the power semiconductor device. Improved power semiconductor devices as well as improved methods for fabricating power semiconductor devices may help with solving these and other problems.

### SUMMARY

Various aspects pertain to a power semiconductor device, comprising: a substrate comprising a patterned metallization on an electrically insulating body; at least one first power transistor die of a first transistor type attached to the substrate; at least one second power transistor die of a second transistor type different from the first transistor type attached to the substrate; and a stray inductance magnifier electrically connected to the first power transistor die and configured to increase a stray inductance of the first power transistor die with respect to a stray inductance of the second power transistor die, wherein load terminals of the first power transistor die and load terminals of the second power transistor die are electrically connected in parallel via the patterned metallization to form a first topological switch.

Various aspects pertain to a method for fabricating a power semiconductor device, the method comprising: providing a substrate comprising a patterned metallization on an electrically insulating body; attaching at least one first power transistor die of a first transistor type to the substrate; attaching at least one second power transistor die of a second transistor type different from the first transistor type to the substrate; connecting in parallel load terminals of the first power transistor die with load terminals of the second power transistor die via the patterned metallization, thereby forming a first topological switch; and connecting a stray inductance magnifier to the first power transistor die, the stray inductance magnifier configured to increase a stray inductance of the first power transistor die with respect to a stray inductance of the second power transistor die.

Various aspects pertain to a power semiconductor device, comprising: a substrate comprising a patterned metallization on an electrically insulating body; at least one first power transistor die of a first transistor type attached to the substrate via a first joint of a first joint type; and at least one second power transistor die of a second transistor type different from the first transistor type attached to the substrate via a second joint of a second joint type, different from the first joint type, wherein the first power transistor die and the second power transistor die are electrically connected in parallel via the patterned metallization to form a first topological switch, and wherein the first joint type has a higher power cycling robustness than the second joint type.

Those skilled in the art will recognize additional features and advantages upon reading the following detailed description, and upon viewing the accompanying drawings.

### BRIEF DESCRIPTION OF THE DRAWINGS

The present disclosure is illustrated by way of example, and not by way of limitation, in the figures of the accompanying drawings in which like reference numerals refer to similar or identical elements. The elements of the drawings are not necessarily to scale relative to each other. The features of the various illustrated examples can be combined unless they exclude each other.

FIG. 1 illustrates a schematic plan view of a power semiconductor device comprising a first power transistor die of a first type and a second power transistor die of a different second type connected to form a topological switch. The power semiconductor device further comprises a stray inductance magnifier configured to increase a stray inductance of the first power transistor die with respect to a stray inductance of the second power transistor die in order to improve the switching characteristics of the power transistor dies.

FIG. 2 illustrates an exemplary electrical circuit comprising a topological switch which may be realized in the power semiconductor device of FIG. 1.

FIGS. 3A and 3B illustrate the load current flowing through the first power transistor die, through the second power transistor die and the sum current flowing through both dies for turn-on (FIG. 3A) and turn-off (FIG. 3B). FIGS. 3A and 3B in particular illustrate the effect of the stray inductance magnifier on the load current.

FIG. 4 schematically illustrates a system comprising the power semiconductor device of FIG. 1 connected to an exemplary driver board.

FIG. 5 illustrates a schematic plan view of a further power semiconductor device which comprises a particular example of a stray inductance magnifier.

FIG. 6 illustrates a schematic plan view of a further power semiconductor device which comprises a different particular example of a stray inductance magnifier.

FIG. 7 illustrates a schematic plan view of a further power semiconductor device which comprises both stray inductance magnifier of the power semiconductor devices of FIGS. 5 and 6.

FIG. 8 illustrates a schematic plan view of a further power semiconductor device, wherein the first power transistor die is joined to the substrate using a first joint type and the second power transistor die is joined to the substrate using a different second joint type.

FIG. 9 illustrates a schematic plan view of yet a further power semiconductor device, wherein the substrate comprises a first and a second partial substrate which are of different substrate types and wherein the first power transistor die is arranged over the first partial substrate and the second power transistor die is arranged over the second partial substrate.

FIG. 10 is a flow chart of an exemplary method for fabricating a power semiconductor device.

### DETAILED DESCRIPTION

In the following detailed description, known structures and elements are shown in schematic form in order to facilitate describing one or more aspects of the disclosure. In this regard, directional terminology, such as "top", "bottom", "left", "right", "upper", "lower" etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms "include", "have", "with" or other variants thereof are used in either the detailed description or the claims, such terms are intended to be inclusive in a manner similar to the term "comprise". The terms "coupled" and "connected", along with derivatives thereof may be used. It should be understood that these terms may be used to indicate that two elements cooperate or interact with each other regardless whether they are in direct physical or electrical contact, or they are not in direct contact with each other; intervening elements or layers may be provided between the "bonded", "attached", or "connected" elements. However, it is also possible that the "bonded", "attached", or "connected" elements are in direct contact with each other. Also, the term "exemplary" is merely meant as an example, rather than the best or optimal.

An efficient power semiconductor device as well as an efficient method for fabricating a power semiconductor device may for example reduce material consumption, ohmic losses, chemical waste, etc. and may thus enable energy and/or resource savings. Improved power semiconductor devices as well as improved methods for fabricating a power semiconductor device, as specified in this description, may thus at least indirectly contribute to green technology solutions, i.e. climate-friendly solutions providing a mitigation of energy and/or resource use.

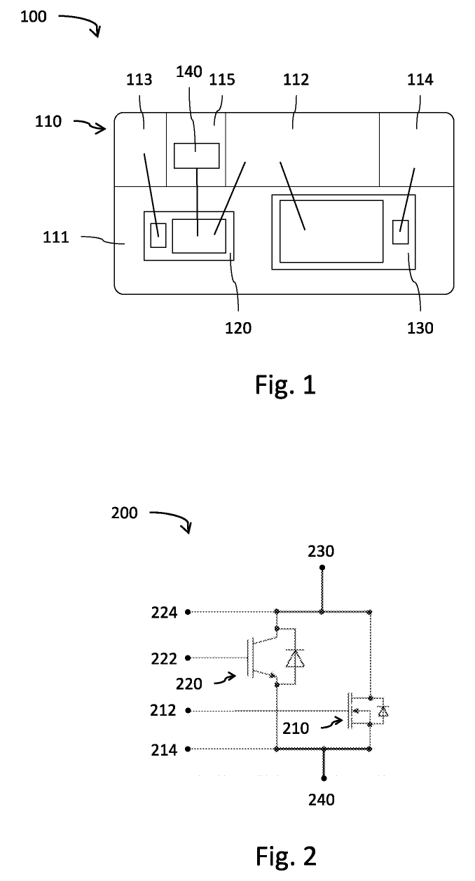

FIG. 1 schematically shows a power semiconductor device 100 comprising a substrate 110, a first power transistor die 120, a second power transistor die 130 and a stray inductance magnifier 140.

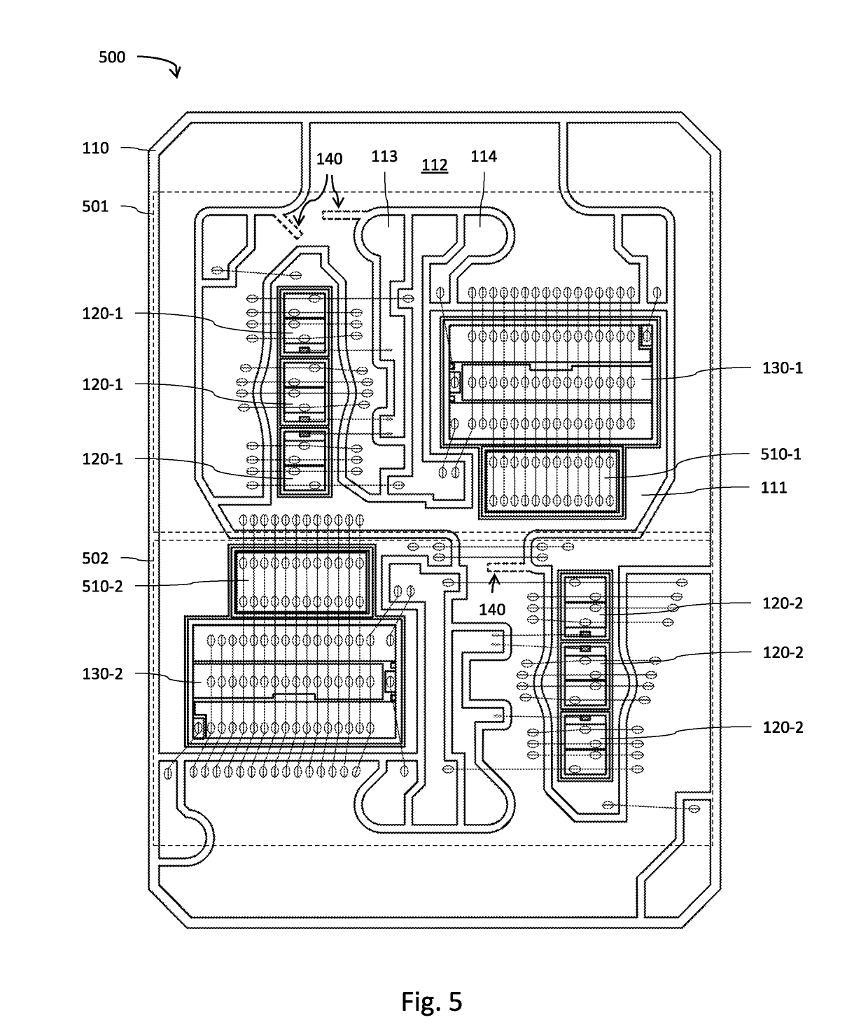

The power semiconductor device 100 may, for example, comprise a single topological switch provided by the first and second power transistor dies 120, 130 connected in parallel. In particular, load terminals of the first power transistor die 120 and load terminals of the second power transistor die 130 are electrically connected in parallel via the patterned metallization to form a first topological switch, compare e.g. FIGS. 5-7. According to another example, the power semiconductor device 100 may comprise a plurality of such switches which may be provided by a plurality of respective first and second power transistor dies 120, 130. In the latter case, the power semiconductor device 100 may, for example, comprise a circuit like a half bridge circuit, a full bridge circuit, a B6-bridge circuit, a converter circuit, an inverter circuit, etc.

The power semiconductor device 100 may be configured for use in any suitable application, for example in automotive applications, industrial applications and/or household applications. The power semiconductor device 100 may in particular be used in motor drive applications for an electric vehicle and may for example be part of a main inverter of an electric vehicle.

The substrate 110 comprises a patterned metallization arranged on an electrically insulating body. The power transistor dies 120, 130 are arranged on and electrically connected to the patterned metallization. The patterned metallization may comprise any suitable number of metallic islands and/or metallic tracks separated from each other by grooves. The substrate 110 may for example be a substrate of the type direct bonded copper (DBC), direct bonded aluminum (DBA), active metal brazed (AMB), or insulated metal substrate (IMS).

According to an example, the power transistor dies 120, 130 may be arranged on a common first metallic island 111, wherein power terminals on the lower sides of the power transistor dies 120, 130 are connected in parallel by the first metallic island 111. Furthermore, power terminals on the upper sides of the power transistor dies 120, 130 may be connected in parallel by a second metallic island 112. A gate terminal of the first power transistor die 120 may be connected to third metallic island 113 and a gate terminal of the second power transistor die 130 may be connected to a fourth metallic island 114 to enable simple end of line testing. However, the gate terminals 113 and 114 may also be connected to a common metallic island, depending on the desired system integration. In the example shown in FIG. 1, the stray inductance magnifier 140 is connected to a fifth metallic island 115. However, the stray inductance magnifier 140 may for example also be connected to any other suitable metallic island.

According to an example, the power semiconductor device 100 comprises a single first power transistor die 120 and a single second power transistor die 130. However, it is also possible that the power semiconductor device 100 comprises a plurality of first power transistor dies 120 and/or a plurality of second power transistor dies 130. For example, the power semiconductor device 100 may comprise two, three, four, five, etc. first power transistor dies 120 and the same number or a different number of second power transistor dies 130. Some or all of the first power transistor dies 120 and some or all of the second power transistor dies 130 may be connected in parallel.

The at least one first power transistor die 120 is of a first transistor type and the at least one second power transistor die 130 is of a second transistor type, different from the first transistor type. For example, the first power transistor die 120 is a MOSFET die (metal–oxide–semiconductor field-effect transistor die) and the second power transistor die 130 is an IGBT die (insulated-gate bipolar transistor die). In this case, the power semiconductor device 100 may further comprise a diode die (not shown) electrically connected antiparallel with the second power transistor die 130 (the IGBT die) to provide a freewheeling current path.

The first and second power transistor dies 110, 120 may for example be soldered or sintered or glued with conductive glue to the patterned metallization of the substrate 110. According to an example, the same joining technique and/or the same joining material is used to join the first power transistor die 120 and the second power transistor die 130 to the substrate 110. According to another example, different joining techniques and/or different joining materials are used for the first and second power transistor dies 120, 130. For example, sintering may be used for joining the first power transistor die 120 to the substrate 110 and soldering may be used for joining the second power transistor die 130 to the substrate 110 or a diffusion solder may be used for joining the first power transistor die 120 to the substrate 110 and a soft solder may be used for joining the second power transistor die 130 to the substrate 110.

The stray inductance magnifier 140 is electrically connected to the first power transistor die 120. For example, the stray inductance magnifier 140 may be connected to the first power transistor die 120 by a bond wire or a clip or via the patterned metallization of the substrate 110.

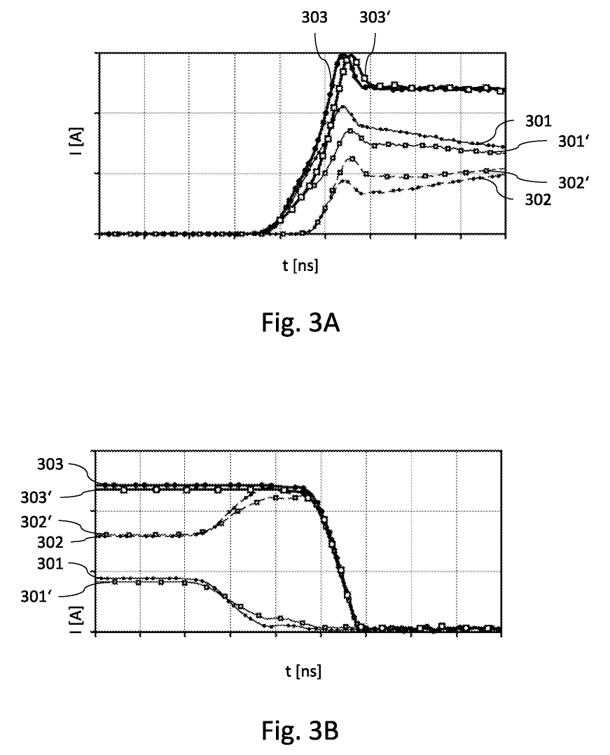

The stray inductance magnifier 140 is configured to increase a stray inductance of the first power transistor die 120 with respect to a stray inductance of the second power transistor die 130. This increase of the stray inductance causes a delay of the turn-on of the first power transistor die 120 with respect to the second power transistor die 130 as well as a reduction of the maximum current flowing through the first power transistor die 120 and consequently an increase of the maximum current flowing through the second power transistor die 130 during turn-on. This is explained in greater detail with respect to FIGS. 3A and 3B.

According to an example, the stray inductance magnifier 140 comprises or consists of a narrowing of a conductive track of the patterned metallization of the substrate 110. Additionally or alternatively, the stray inductance magnifier 140 comprises or consists of a meander structure or a dead end extending into a metallic island of the patterned metallization. Additionally or alternatively, the stray inductance magnifier 140 comprises or consists of a negative feedback loop in a gate control path of the first power transistor die 120, wherein the negative feedback loop is configured to slow down switching slopes of the first power transistor die 120 relative to the second power transistor die 130. Specific examples of the stray inductance magnifier 140 are explained in greater detail with respect to FIGS. 5-7.

FIG. 2 shows an exemplary electrical circuit 200 which, according to an example, may be comprised in the power semiconductor device 100.

The electrical circuit comprises a first power transistor 210 and a second power transistor 220. According to a specific example, the first power transistor is a MOSFET and the second power transistor 220 is an IGBT. In the power semiconductor device 100, the first power transistor 210 may be provided by the first power transistor die 120 and the second power transistor 220 may be provided by the second power transistor die 130.

As shown in FIG. 2, first power terminals of the first and second power transistors 210, 220 are connected in parallel and second power terminals of the first and second power transistors 210, 220 are also connected in parallel. In the case of a MOSFET and an IGBT, the collector terminal of the IGBT may be connected in parallel with the drain terminal of the MOSFET and the emitter terminal of the IGBT may be connected in parallel with the source terminal of the MOSFET.

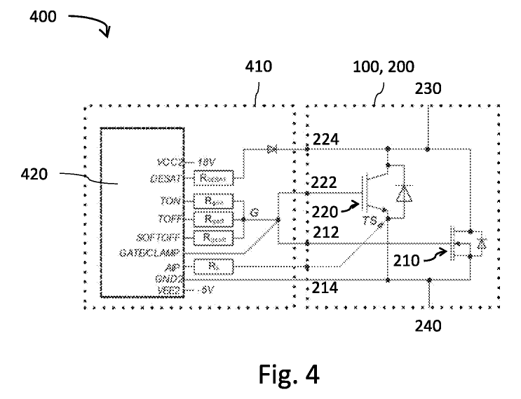

The first power terminals of the first and second power transistors 210, 220 are connected to a first power terminal 230 and the second power terminals of the first and second power transistors 210, 220 are connected to a second power terminal 240. In the power semiconductor device 100, the power terminals 230, 240 are external terminals of the power semiconductor device 100. The electrical circuit 200 further comprises a first gate terminal 212, a second gate terminal 222, an auxiliary source terminal 214 and an auxiliary collector terminal 224. In the power semiconductor device 100, the terminals 212-224 are configured to be connected to a gate driver for driving the first and second power transistors 210, 220 (compare FIG. 4).

The electrical circuit 200 (and the power semiconductor device 100) may for example be configured to be operated as follows: under light load conditions, when the load current being switched by the electrical circuit 200 is considerable lower than the maximum load current the power semiconductor device 100 is rated for, all or almost all of the load current flows through the first power transistor 210 (i.e. the first power transistor die 120) and no or almost no load current flows through the second power transistor 220 (i.e. the second power transistor die 130). However, under heavy load conditions, when the load current is close to or even equal to the maximum load current, a large amount of the load current flows through the second power transistor 220 and only a comparatively small amount of the load current flows through the first power transistor 210, e.g. the load current flowing through the first power transistor is still within its rated current.

Many applications, for example electric vehicles, are operated under light load conditions most of the time and only comparatively rarely under heavy load conditions. In order to increase system efficiency, the first transistor die 120 should be highly efficient, like for example a SiC MOSFET die which however is comparatively expensive. In order to save costs, the first transistor die 120 can be a small die, not designed to support the full load current. Therefore, at heavy load conditions the second power transistor die 130, which can for example be a less efficient but also less expensive Si IGBT die, kicks in and relieves the first power transistor die 120.

FIG. 3A shows the load current as a function of time during the turn-on phase of a switching cycle at heavy load conditions, according to a specific example of the power semiconductor device 100. Curves 301 and 301’ show the current flowing through the first power transistor die 120. Curves 302 and 302’ show the current flowing through the second power transistor die 130. And Curves 303 and 303’ show the sum of the current flowing through the first and second power transistor die 120, 130. Curves 301, 302 and 303 show the load current flowing through the first and second power transistor dies 120, 130 and the sum current flowing through both dies, respectively, in the case that no stray inductance magnifier 140 is present. Curves 301’, 302’ and 303’ show the same currents in the case that the stray inductance magnifier 140 is present.

FIG. 3B shows the load current as a function of time during the turn-off phase of a switching cycle at heavy load conditions. The numbering of the curves is the same as in FIG. 3A.

As shown in FIG. 3A, the first power transistor die 120 may have an earlier turn-on than the second power transistor die 130. In order to increase the lifetime of the first power transistor die 120, it may be desirable to reduce stress induced by turn-on of the small first power transistor die 120. As shown in FIG. 3A, the stray inductance magnifier 140 is configured to reduce the slope of the turn-on curve 301’ (the load current flowing through the first power transistor die 120) which in turn causes a larger part of the overall load current to flow through the second power transistor die 130 during turn-on. This reduces the turn-on stress in the first power transistor die 120. It should be noted that the impact of the modification introduced by the stray inductance magnifier 140 on the sum of the switching losses is very small or even negligible.

As shown in FIG. 3B, depicting the turn-off phase, the first power transistor die 120 switches off first. At this point, the full load current flows through the second power transistor die 130 before the second power transistor die 130 also switches off. The stray inductance magnifier 140 does not significantly impact the turn-off.

The stray inductance magnifier 140 may furthermore positively affect short circuit conditions by causing the gate driver desaturation circuit to react faster. In an example with nominal -non short circuit - load switching speed of 10kA/us and short circuit detection times of about 600 ns (time from turn-on till gate driver start to turn-off), the stray inductance magnification causes the gate driver desaturation circuit to react about 50ns faster and reduce 2kA peak short circuit current..

In sum, the stray inductance magnifier 140 increases a stray inductance of the first power transistor die 120 with respect to a stray inductance of the second power transistor die 130, thereby slowing down the switching slopes of the first transistor die 120 relative to the second power transistor die 130, at least during turn-on. Since the switching timing of the first and second power transistor dies 120, 130 is optimized in this manner via the use of the stray inductance magnifier 140, a driver integrated circuit does not need to be configured to perform this function, reducing driver complexity.

FIG. 4 schematically shows a system 400 comprising the power semiconductor device 100 (comprising the electrical circuit 200) and a driver board 410 connected to the power semiconductor device 100. The driver board 410 comprises a driver chip 420 for controlling the switching in the power semiconductor device 100.

In the example shown in FIG. 4, the power semiconductor device 100 comprises the first gate terminal 212 and the second gate terminal 222. However, these two gate terminals 212, 222 are combined on the driver board 410 such that a common gate control voltage signal from the driver chip 420 is received by the gate terminals 212, 222. In other words, the first and second power transistor dies 120, 130 are switched by the driver chip 420 via a common signal. According to another example of the system 400, the driver chip 420 comprises two individual outputs connected to the gate terminals 212, 222 such that the power transistor dies 120, 130 can be driven individually. According to yet another example, the gates of the power transistor dies 120, 130 are connected internally such that the power semiconductor device 100 comprises a single external gate terminal connected to the driver board 420.

As noted further above, the driver chip 420 can provide a common gate control signal for switching both power transistor dies 120, 130 without or almost without reducing electrical performance and chip lifetime because switching characteristics of the power transistor dies 120, 130 are adjusted to each other inside the power semiconductor device 100 itself via the stray inductance magnifier 140. Gate driver chip 420 illustrates only an extract of the most important signals on the high voltage side towards the power switch. The low voltage side towards the control logic is not shown due to simplification.

FIG. 5 shows a schematic plan view of a further power semiconductor device 500 which may be similar or identical to the power semiconductor device 100, except for the differences described in the following. In particular, the power semiconductor device 500 comprises a first topological switch 501 and a second topological switch 502 which may for example be connected to form a half bridge circuit.

The first topological switch 501 comprises a plurality of first power transistor dies 120-1, a second power transistor die 130-1 and a diode 510-1 connected antiparallel with the second power transistor die 130-1. Likewise, the second topological switch 502 comprises a further plurality of first power transistor dies 120-2, a further second power transistor die 130- 2 and a further diode 510-2 connected antiparallel with the further second power transistor die 130-2.

The first and second topological switches 501, 502 of the power semiconductor device 500 furthermore comprises stray inductance magnifier 140. In the particular example shown in FIG. 5, the stray inductance magnifier 140 consist of meander structures or dead ends extending into metallic islands of the patterned metallization of the substrate 110. In the example of FIG. 5, the meander structures or dead ends extend into the first and second metallic islands 111, 112. The dead ends or meander structures may be configured such that the switching slopes of turn-on and turn-off of the power transistor dies 120, 130 are modified as explained with respect to FIGS. 3A and 3B. This may for example comprise placing the meander structures or dead ends close to the first power transistor dies 120.

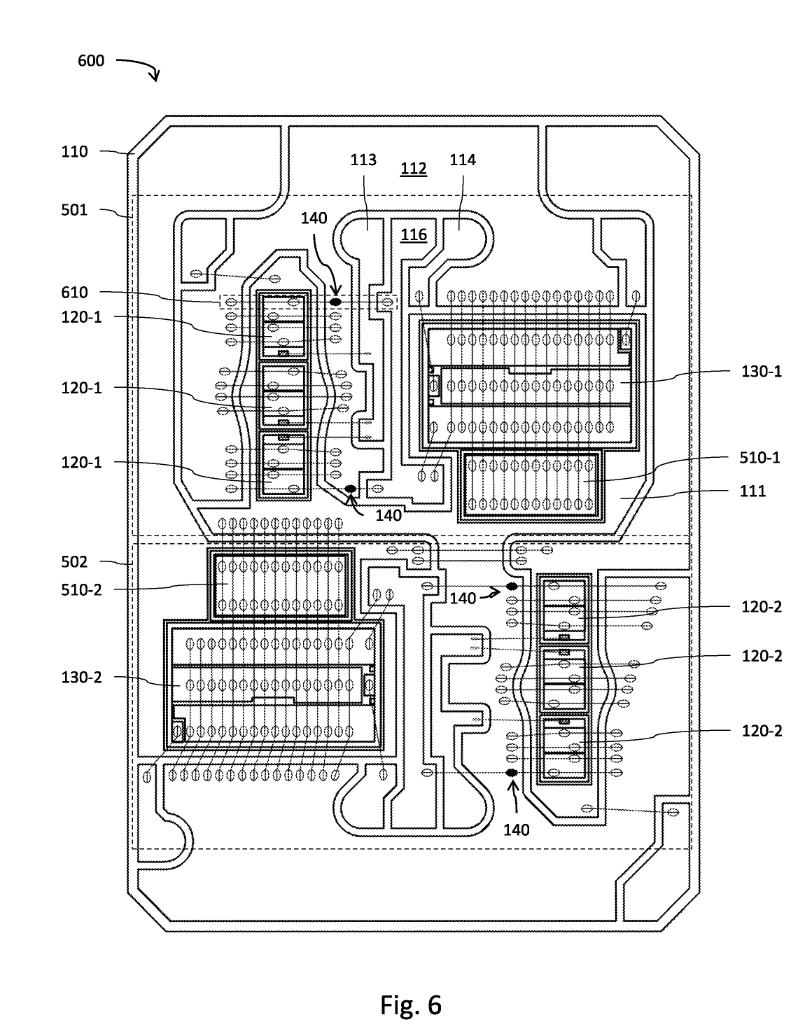

FIG. 6 shows a schematic plan view of a further power semiconductor device 600 which may be similar or identical to the power semiconductor device 500, except for the differences described in the following.

In particular, the power semiconductor device 600 does not comprise a stray inductance magnifier 140 in the form of meander structures or dead ends in the patterned metallization of the substrate 110. Instead, the stray inductance magnifier 140 consist of negative feedback loops in gate control paths of the first power transistor dies 120-1, 120-2. In particular, the negative feedback loops of the first and second topological switches 501, 502 comprise bond wires connected to specific metallic islands of the patterned metallization of the substrate 110, wherein the specific metallic islands are part of a respective load current path of the power semiconductor device 600.

For example, the bond wire 610 is configured to connect a load terminal on the upper side of one of the first power transistor dies 120-1 to a sixth metallic island 116, for example in order to provide connection to an external sensing contact pin on the sixth metallic island 116. However, in order to increase the stray inductance of the first power transistor dies 120-1, the bond wire 610 is additionally connected to the second metallic island 112 which is configured to carry a load current. Such specifically added wire bond connections (i.e. additional ball-bonds or wedge bonds on a bond wire) to further metallic islands are indicated in FIG. 6 using filled ovals and provide the stray inductance magnifier 140. The wire bond connections that are not part of the stray inductance magnifier 140 are represented in FIG. 6 using empty ovals.

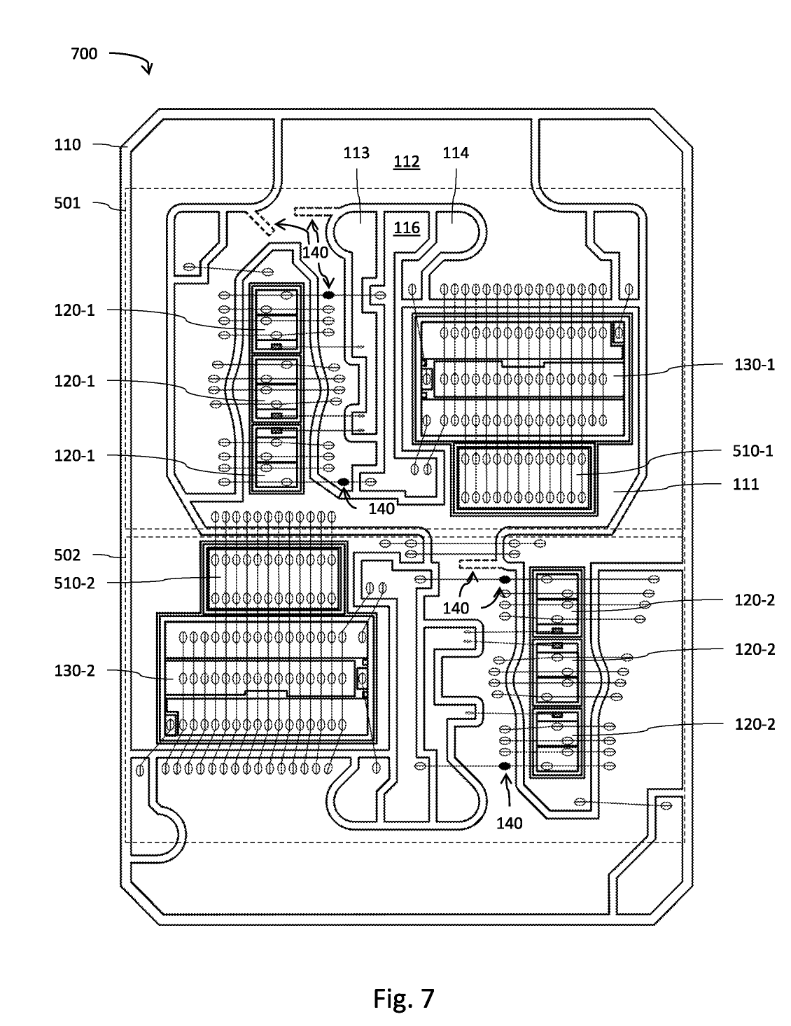

FIG. 7 shows a schematic plan view of a further power semiconductor device 700 which may be similar or identical to the power semiconductor devices 500 and 600, except for the differences described in the following.

In particular, the power semiconductor device 700 comprises stray inductance magnifier 140 in the form of both the meander structures or dead ends of the power semiconductor device 500 and the additional ball-bonds or wedge-bonds of the power semiconductor device 600. By using both types of stray inductance magnifier 140 in a power semiconductor device, it may for example be possible to more readily adjust the switching characteristics of the power transistor dies 120, 130 in the desired manner.

According to an example of the power semiconductor devices 100 to 700, a gate-source threshold voltage of the first power transistor die(s) 120 is about 80% or less, or about 70% or less, or about 60% or less of a gate-emitter threshold voltage of the second power transistor die(s) 130. Furthermore, a gate time constant formed by an input capacitance and a gate resistance of the first power transistor die(s) 120 may for example be about 60% or less, or about 50% or less, or about 40% or less of a gate time constant of the second power transistor die(s) 130.

According to an example of the power semiconductor devices 100 to 700, a size of the first power transistor die(s) 120 as viewed from above the power semiconductor device is about 60% or less, or about 50% or less, or about 40% or less of a size of the second power transistor die(s) 130 (in particular, the total size of all first power transistor dies 120-1 or 120-2 of the respective topological switch 501 or 502 may be in the above-mentioned range compared to the total size of all second power transistor dies 130 of the respective topological switch).

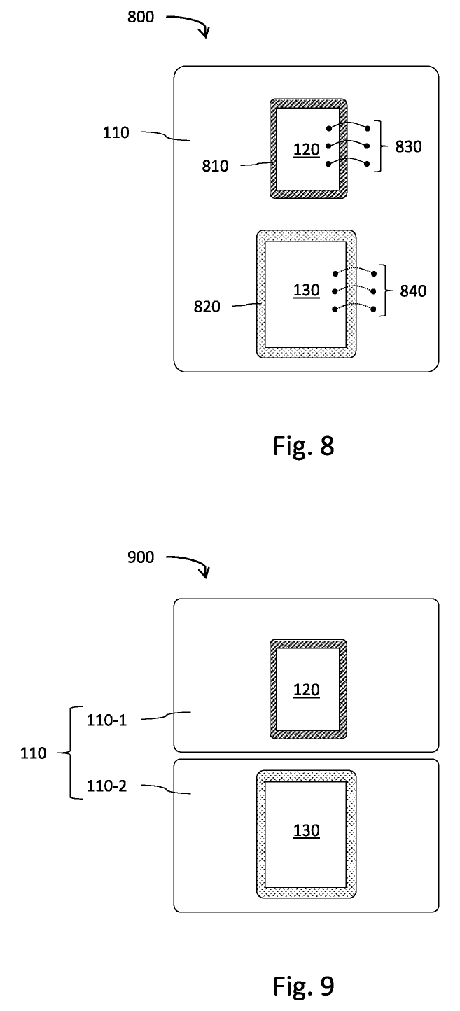

FIG. 8 shows a schematic plan view of a further power semiconductor device 800 which may be similar or identical to any of the power semiconductor devices 100 to 700, except for the differences described in the following. In particular, the power semiconductor device 800 does not necessarily comprise the stray inductance magnifier 140.

The power semiconductor device 800 comprises the substrate 110, the at least one first power transistor die 120 which is attached to the substrate 110 via a first joint 810 of a first joint type and the at least one second power transistor die 130 which is attached to the substrate 110 via a second joint 820 of a second joint type, different from the first joint type.

Furthermore, the first power transistor die 120 is of a first transistor type, e.g. a MOSFET, and the second power transistor die 130 is of a second transistor type different from the first transistor type, e.g. an IGBT. Similar to the power semiconductor devices 100 to 700, the first power transistor die 120 and the second power transistor die 130 are electrically connected in parallel via the patterned metallization of the substrate 110 to form at least a first topological switch.

The first joint type (and consequently the first joint 810) has a higher power cycling robustness than the second joint type (and consequently the second joint 820). In this context, “having a higher power cycling robustness” may mean that the first joint type can undergo a larger number of power cycles of the power semiconductor device 800 at a given temperature before joint failure than the second joint type. For example, the first joint 810 comprises a comparatively robust diffusion solder layer or a sintered layer and the second joint 820 comprises a comparatively less robust soft solder layer.

According to an example, the first power transistor die 120 is electrically connected to the substrate 110 via first bond wires 830 of a first bond wire type and the second power transistor die 130 is electrically connected to the substrate 110 via second bond wires 840 of a second bond wire type which is different from the first bond wire type. For example, the first bond wires 830 may be Cu wires and the second bond wires 840 may be Al wires. Additionally or alternatively, the first bond wires 830 may be mechanically fixed to the first power transistor die 120 and/or to the substrate 110 with epoxy glue and no epoxy glue fixes the second bond wires 840 to the second power transistor die 130 and/or to the substrate 110. The epoxy glue may be configured to increase the mechanical robustness of the bond wire connection between the first power transistor die 120 and the substrate 110.

Generally speaking, mechanical and/or electrical connections between the first power transistor die 120 and the substrate 110 may have better electrical and mechanical properties but may also be comparatively more expensive than such connections between the second power transistor die 130 and the substrate 110.

FIG. 9 shows a schematic plan view of a further power semiconductor device 900 which may be similar or identical to any of the power semiconductor devices 100 to 800, except for the differences described in the following.

In particular, the substrate 110 of the power semiconductor device 900 comprises a first partial substrate 110-1 and a second partial substrate 110-2. The first power transistor die 120 is attached to the first partial substrate 110-1 and the second power transistor die 130 is attached to the second partial substrate 110-2. Furthermore, the first partial substrate 110-1 is of a first substrate type and the second partial substrate 110-2 is of a different second substrate type.

According to an example, the first substrate type has a higher power cycling robustness than the second substrate type. For example, the first substrate type may be an AMB comprising a silicon nitride ceramic and the second substrate type may be a DBC with a comparatively cheaper ceramic and/or a DBC with a comparatively thinner copper layer or for example a DBA, etc.

Generally speaking, the first partial substrate 110-1 may have a comparatively low thermal resistance and high power cycling robustness and may be comparatively expensive and the second partial substrate 110-2 may have a comparatively high thermal resistance and low power cycling robustness but may be comparatively cheap.

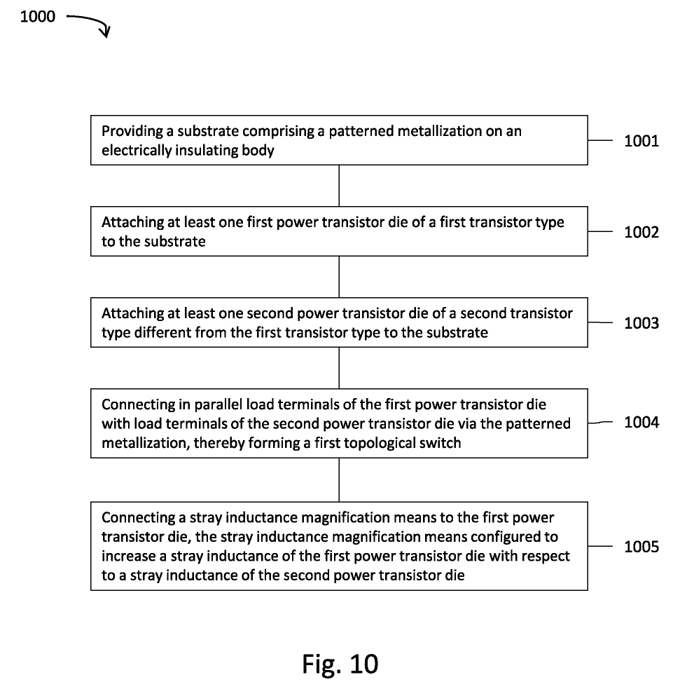

FIG. 10 is a flow chart of an exemplary method 1000 for fabricating a power semiconductor device. The method 10000 may for example be used to fabricate any of the power semiconductor devices 100 to 900.

The method 10000 comprises at 10001 a process of providing a substrate comprising a patterned metallization on an electrically insulating body, at 10002 a process of attaching at least one first power transistor die of a first transistor type to the substrate, at 10003 a process of attaching at least one second power transistor die of a second transistor type different from the first transistor type to the substrate, at 10004 a process of connecting in parallel load terminals of the first power transistor die with load terminals of the second power transistor die via the patterned metallization, thereby forming a first topological switch, and at 10005 a process of connecting a stray inductance magnifier to the first power transistor die, the stray inductance magnifier configured to increase a stray inductance of the first power transistor die with respect to a stray inductance of the second power transistor die.

In the following, the power semiconductor device and the method for fabricating a power semiconductor device are further explained using specific examples.

Example 1 is a power semiconductor device, comprising: a substrate comprising a patterned metallization on an electrically insulating body; at least one first power transistor die of a first transistor type attached to the substrate; at least one second power transistor die of a second transistor type different from the first transistor type attached to the substrate; and a stray inductance magnifier electrically connected to the first power transistor die and configured to increase a stray inductance of the first power transistor die with respect to a stray inductance of the second power transistor die; wherein load terminals of the first power transistor die and load terminals of the second power transistor die are electrically connected in parallel via the patterned metallization to form a first topological switch.

Example 2 is the power semiconductor device of example 1, wherein the inductance magnifier comprises or consists of a narrowing of a conductive track of the patterned metallization and/or a meander structure or a dead end extending into a metallic island of the patterned metallization.

Example 3 is the power semiconductor device of example 1 or 2, wherein the inductance magnifier comprises a negative feedback loop in a gate control path of the first power transistor die, the negative feedback loop configured to slow down switching slopes of the first power transistor die relative to the second power transistor die.

Example 4 is the power semiconductor device of example 3, wherein the negative feedback loop comprises a bond wire connected to a metallic island of the patterned metallization, the metallic island being part of a load current path of the power semiconductor device.

Example 5 is the power semiconductor device of one of the preceding examples, wherein the first power transistor die is a SiC die and the second power transistor die is a Si die.

Example 6 is the power semiconductor device of one of the preceding examples, wherein the first power transistor die is a MOSFET die and the second power transistor die is an IGBT die.

Example 7 is the power semiconductor device of example 5 or 6, further comprising: a diode die electrically connected antiparallel with the IGBT die.

Example 8 is the power semiconductor device of example 6 or 7, wherein a gate-source threshold voltage of the first power transistor die is 70% or less of a gate-emitter threshold voltage of the second power transistor die and a gate time constant formed by an input capacitance and a gate resistance of the first power transistor die is 50% or less of a gate time constant of the second power transistor die.

Example 9 is the power semiconductor device of one of the preceding examples, wherein a size of the first power transistor die is 50% or less of a size of the second power transistor die.

Example 10 is a method for fabricating a power semiconductor device, the method comprising: providing a substrate comprising a patterned metallization on an electrically insulating body; attaching at least one first power transistor die of a first transistor type to the substrate; attaching at least one second power transistor die of a second transistor type different from the first transistor type to the substrate; connecting in parallel load terminals of the first power transistor die with load terminals of the second power transistor die via the patterned metallization, thereby forming a first topological switch; and connecting a stray inductance magnifier to the first power transistor die, the stray inductance magnifier configured to increase a stray inductance of the first power transistor die with respect to a stray inductance of the second power transistor die.

Example 11 is the method of example 10, the inductance magnifier comprises or consists of a narrowing of a conductive track of the patterned metallization and/or a meander structure or a dead end extending into a metallic island of the patterned metallization.

Example 12 is the method of example 10 or 11, wherein the inductance magnifier comprises a negative feedback loop in a gate control path of the first power transistor die, the negative feedback loop configured to slow down switching slopes of the first power transistor die relative to the second power transistor die.

Example 13 is a power semiconductor device, comprising: a substrate comprising a patterned metallization on an electrically insulating body; at least one first power transistor die of a first transistor type attached to the substrate via a first joint of a first joint type; and at least one second power transistor die of a second transistor type different from the first transistor type attached to the substrate via a second joint of a second joint type, different from the first joint type; wherein the first power transistor die and the second power transistor die are electrically connected in parallel via the patterned metallization to form a first topological switch; and wherein the first joint type has a higher power cycling robustness than the second joint type.

Example 14 is the power semiconductor device of example 13, wherein the first joint comprises a diffusion solder layer or a sintered layer and the second joint comprises a soft solder layer.

Example 15 is the power semiconductor device of example 13 or 14, wherein the first power transistor die is electrically connected to the substrate via first bond wires of a first bond wire type and wherein the second power transistor die is electrically connected to the substrate via second bond wires of a second bond wire type, different from the first bond wire type.

Example 16 is the power semiconductor device of example 15, wherein the first bond wires are Cu wires and the second bond wires are Al wires.

Example 17 is the power semiconductor device of example 15 or 16, wherein the first bond wires are mechanically fixed to the first power transistor die and/or to the substrate with epoxy glue and no epoxy glue fixes the second bond wires to the second power transistor die and/or to the substrate.

Example 18 is the power semiconductor device of one of examples 13 to 17, wherein the substrate comprises a first partial substrate and a second partial substrate, wherein the first power transistor die is attached to the first partial substrate and the second power transistor die is attached to the second partial substrate, wherein the first partial substrate is of a first substrate type and the second partial substrate is of a different second substrate type.

Example 19 is the power semiconductor device of example 18, wherein the first substrate type has a higher power cycling robustness than the second substrate type.

Example 20 is an apparatus comprising means for performing the method according to anyone of examples 10 to 12.

Although specific examples have been illustrated and described herein, it will be appreciated by those of ordinary skill in the art that a variety of alternate and/or equivalent implementations may be substituted for the specific examples shown and described without departing from the scope of the present invention. This application is intended to cover any adaptations or variations of the specific examples discussed herein. Therefore, it is intended that this invention be limited only by the claims and the equivalents thereof.

It should be noted that the methods and devices including its preferred embodiments as outlined in the present document may be used stand-alone or in combination with the other methods and devices disclosed in this document. In addition, the features outlined in the context of a device are also applicable to a corresponding method, and vice versa. Furthermore, all aspects of the methods and devices outlined in the present document may be arbitrarily combined. In particular, the features of the claims may be combined with one another in an arbitrary manner.

It should be noted that the description and drawings merely illustrate the principles of the proposed methods and systems. Those skilled in the art will be able to implement various arrangements that, although not explicitly described or shown herein, embody the principles of the invention and are included within its spirit and scope. Furthermore, all examples and embodiments outlined in the present document are principally intended expressly to be only for explanatory purposes to help the reader in understanding the principles of the proposed methods and systems. Furthermore, all statements herein providing principles, aspects, and embodiments of the invention, as well as specific examples thereof, are intended to encompass equivalents thereof.

What is claimed is:

1. A power semiconductor device, comprising:
a substrate comprising a patterned metallization on an electrically insulating body;
a first power transistor die of a first transistor type attached to the substrate;
a second power transistor die of a second transistor type different from the first transistor type attached to the substrate; and
a stray inductance magnifier electrically connected to the first power transistor die and configured to increase a stray inductance of the first power transistor die with respect to a stray inductance of the second power transistor die,
wherein load terminals of the first power transistor die and load terminals of the second power transistor die are electrically connected in parallel via the patterned metallization to form a first topological switch.

2. The power semiconductor device of claim 1, wherein the stray inductance magnifier comprises a narrowing of a conductive track of the patterned metallization and/or a meander structure or a dead end extending into a metallic island of the patterned metallization.

3. The power semiconductor device of claim 1, wherein the stray inductance magnifier comprises a negative feedback loop in a gate control path of the first power transistor die, the negative feedback loop configured to slow down switching slopes of the first power transistor die relative to the second power transistor die.

4. The power semiconductor device of claim 3, wherein the negative feedback loop comprises a bond wire connected to a metallic island of the patterned metallization, the metallic island being part of a load current path of the power semiconductor device.

5. The power semiconductor device of claim 1, wherein the first power transistor die is a SiC die and the second power transistor die is a Si die.

6. The power semiconductor device of claim 1, wherein the first power transistor die is a MOSFET die and the second power transistor die is an IGBT die.

7. The power semiconductor device of claim 6, further comprising:
a diode die electrically connected antiparallel with the IGBT die.

8. The power semiconductor device of claim 6, wherein a gate-source threshold voltage of the first power transistor die is 70% or less of a gate-emitter threshold voltage of the second power transistor die, and wherein a gate time constant formed by an input capacitance and a gate resistance of the first power transistor die is 50% or less of a gate time constant of the second power transistor die.

9. The power semiconductor device of claim 1, wherein a size of the first power transistor die is 50% or less of a size of the second power transistor die.

10. A method for fabricating a power semiconductor device, the method comprising:
providing a substrate comprising a patterned metallization on an electrically insulating body;
attaching a first power transistor die of a first transistor type to the substrate;
attaching a second power transistor die of a second transistor type different from the first transistor type to the substrate;
connecting in parallel load terminals of the first power transistor die with load terminals of the second power transistor die via the patterned metallization, to form a first topological switch; and
connecting a stray inductance magnifier to the first power transistor die, the stray inductance magnifier configured to increase a stray inductance of the first power transistor die with respect to a stray inductance of the second power transistor die.

11. The method of claim 10, wherein the stray inductance magnifier comprises a narrowing of a conductive track of the patterned metallization and/or a meander structure or a dead end extending into a metallic island of the patterned metallization.

12. The method of claim 10, wherein the stray inductance magnifier comprises a negative feedback loop in a gate control path of the first power transistor die, the negative feedback loop configured to slow down switching slopes of the first power transistor die relative to the second power transistor die.

13. A power semiconductor device, comprising:
a substrate comprising a patterned metallization on an electrically insulating body;
a first power transistor die of a first transistor type attached to the substrate via a first joint of a first joint type; and
a second power transistor die of a second transistor type different from the first transistor type attached to the substrate via a second joint of a second joint type, different from the first joint type,
wherein the first power transistor die and the second power transistor die are electrically connected in parallel via the patterned metallization to form a first topological switch,
wherein the first joint type has a higher power cycling robustness than the second joint type.

14. The power semiconductor device of claim 13, wherein the first joint comprises a diffusion solder layer or a sintered layer, and wherein the second joint comprises a soft solder layer.

15. The power semiconductor device of claim 13, wherein the first power transistor die is electrically connected to the substrate via a plurality of first bond wires of a first bond wire type, and wherein the second power transistor die is electrically connected to the substrate via a plurality of second bond wires of a second bond wire type, different from the first bond wire type.

16. The power semiconductor device of claim 15, wherein the first bond wires are Cu wires and the second bond wires are Al wires.

17. The power semiconductor device of claim 15, wherein the first bond wires are mechanically fixed to the first power transistor die and/or to the substrate with epoxy glue, and wherein no epoxy glue fixes the second bond wires to the second power transistor die and/or to the substrate.

18. The power semiconductor device of claim 13, wherein the substrate comprises a first partial substrate and a second partial substrate, wherein the first power transistor die is attached to the first partial substrate and the second power transistor die is attached to the second partial substrate, and wherein the first partial substrate is of a first substrate type and the second partial substrate is of a different second substrate type.

19. The power semiconductor device of claim 18, wherein the first substrate type has a higher power cycling robustness than the second substrate type.
